(19) United States
(12) Patent Application Publication
(10) Pub. No.: US 2024/0224619 A1
(43) Pub. Date: Jul. 4, 2024

(54) DISPLAY APPARATUS AND METHOD OF MANUFACTURING THE SAME

(71) Applicant: Samsung Display Co., LTD., Yongin-si (KR)

(72) Inventors: Myeongho Kim, Yongin-si (KR); Youngoo Kim, Yongin-si (KR); Jaybum Kim, Yongin-si (KR); Kyoungseok Son, Yongin-si (KR); Seunghun Lee, Yongin-si (KR)

(21) Appl. No.: 18/506,623

(22) Filed: Nov. 10, 2023

(30) Foreign Application Priority Data
Dec. 30, 2022 (KR) 10-2022-0191128

(51) Int. Cl. H10K 59/123; H10K 59/12; H10K 59/131

(52) U.S. Cl. CPC H10K 59/123; H10K 59/1201; H10K 59/131; H10K 2102/311

(57) ABSTRACT

A display apparatus includes a substrate having a display area in which display elements are arranged, a first thin-film transistor in the display area and including a first semiconductor layer and a first gate electrode, the first semiconductor layer including an oxide semiconductor and the first gate electrode being insulated from the first semiconductor layer, and a first interlayer insulating layer between the first semiconductor layer and the first gate electrode, wherein the first interlayer insulating layer on the first semiconductor layer has a first length in a first direction, wherein the first gate electrode on the first interlayer insulating layer has a second length in the first direction, and wherein the first length is greater than the second length.

### CROSS-REFERENCE TO RELATED APPLICATION

This application claims priority to and the benefit of Korean Patent Application No. 10-2022-0191128, filed on Dec. 30, 2022, in the Korean Intellectual Property Office, the disclosure of which is incorporated by reference herein in its entirety.

### BACKGROUND

### 1. Field

Aspects of embodiments of the present disclosure relate to a display apparatus and a method of manufacturing the display apparatus.

### 2. Description of the Related Art

A display apparatus visually displays data. A display apparatus may be used as a display unit of miniaturized products such as mobile phones, or used as a display unit of large-scale products such as televisions.

A display apparatus includes a plurality of pixels that receive electric signals and emit light to display images to the outside. Each pixel includes a display element. An organic light-emitting display apparatus may include, for example, an organic light-emitting diode. Generally, an organic light-emitting display apparatus includes a thin-film transistor and an organic light-emitting diode over a substrate, and operates while the organic light-emitting diode emits light spontaneously.

Recently, as the use cases of display apparatuses have diversified, various attempts have been made to a design to improve the quality of the display apparatus.

### SUMMARY

Aspects of some embodiments of the present disclosure are directed to a display apparatus with a high resolution and a method of manufacturing the display apparatus. However, this is merely an example, and the disclosure is not limited thereto.

Additional aspects will be set forth in part in the description which follows and, in part, will be apparent from the description, or may be learned by practice of the presented embodiments of the disclosure.

According to some embodiments, there is provided a display apparatus including: a substrate having a display area in which display elements are arranged; a first thin-film transistor in the display area and including a first semiconductor layer and a first gate electrode, the first semiconductor layer including an oxide semiconductor and the first gate electrode being insulated from the first semiconductor layer; and a first interlayer insulating layer between the first semiconductor layer and the first gate electrode, wherein the first interlayer insulating layer on the first semiconductor layer has a first length in a first direction, wherein the first gate electrode on the first interlayer insulating layer has a second length in the first direction, and wherein the first length is greater than the second length.

In some embodiments, the display apparatus further includes a first gate insulating layer covering the first gate electrode.

In some embodiments, the display apparatus further includes: a bottom metal layer on the substrate; and a buffer layer on the bottom metal layer.

In some embodiments, the display apparatus further includes a second interlayer insulating layer directly on at least a portion of the buffer layer and defining a contact hole therein.

In some embodiments, the display apparatus further includes a first connection electrode on the second interlayer insulating layer.

In some embodiments, the first connection electrode is electrically connected to the bottom metal layer through a contact hole defined in the second interlayer insulating layer and the buffer layer.

In some embodiments, the display apparatus further includes: a lower electrode directly on the buffer layer; and an upper electrode over the lower electrode, wherein the upper electrode and the lower electrode form a capacitor.

In some embodiments, the first gate insulating layer is between the lower electrode and the upper electrode.

In some embodiments, the display apparatus further includes a second gate electrode on the first gate insulating layer.

In some embodiments, the second gate electrode is electrically connected to the bottom metal layer through a contact hole defined in the first gate insulating layer and the buffer layer.

In some embodiments, the display apparatus further includes: a second gate insulating layer on the first gate insulating layer; and a second connection electrode, a source electrode, and a drain electrode on the second gate insulating layer.

In some embodiments, the second connection electrode is electrically connected to the upper electrode of the capacitor through a contact hole defined in the first interlayer insulating layer, and the source electrode and the drain electrode are electrically connected to the first semiconductor layer through contact holes defined in the first interlayer insulating layer.

In some embodiments, the display apparatus further includes: a first organic insulating layer on the second connection electrode; and a third connection electrode on the first organic insulating layer.

In some embodiments, the third connection electrode is electrically connected to the source electrode or the drain electrode through a contact hole defined in the first organic insulating layer.

According to some embodiments, there is provided a method of manufacturing a display apparatus, the method including: forming a first semiconductor layer on a substrate, the first semiconductor layer including an oxide semiconductor; positioning a material for forming an interlayer insulating layer on the first semiconductor layer; forming a first interlayer insulating layer by patterning the material for forming the interlayer insulating layer; and forming a first gate electrode on the first interlayer insulating layer, wherein the first interlayer insulating layer on the first semiconductor layer has a first length in a first direction, wherein the first gate electrode on the first interlayer insulating layer has a second length in the first direction, and wherein the first length is greater than the second length.

In some embodiments, the method further includes, before the forming of the first semiconductor layer on the substrate: forming a bottom metal layer on the substrate; and forming a buffer layer on the bottom metal layer, wherein the first semiconductor layer includes the oxide semiconductor.

In some embodiments, during the forming of the first interlayer insulating layer by patterning the material for forming the interlayer insulating layer, a second interlayer insulating layer is formed by patterning the material for forming the interlayer insulating layer.

In some embodiments, during the forming of the first gate electrode on the first interlayer insulating layer, a first connection electrode is formed on the second interlayer insulating layer, and a lower electrode is formed on the buffer layer.

In some embodiments, the first connection electrode is electrically connected to the bottom metal layer through a contact hole defined in the second interlayer insulating layer.

In some embodiments, the method further includes: forming a first gate insulating layer on the first gate electrode, the lower electrode, and the first connection electrode; and forming an upper electrode on the first gate insulating layer, wherein the upper electrode and the lower electrode constitute a capacitor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to some embodiments of the present disclosure;

FIG. 2 is a schematic equivalent circuit diagram of a display element of a display apparatus and a sub-pixel circuit electrically connected thereto according to some embodiments of the present disclosure;

FIGS. 3 and 4 are schematic cross-sectional views of a display apparatus according to some embodiments of the present disclosure;

FIGS. 5A and 5B are I(current)-V(voltage) graphs for a first semiconductor layer according to a length of a first gate electrode in a first direction; and

FIGS. 6, 7, 8A to 8B, 9A to 9B, 10A to 10B, and 11A to 11B are schematic cross-sectional views of a display apparatus, showing a method of manufacturing the display apparatus according to some embodiments of the present disclosure.

### DETAILED DESCRIPTION

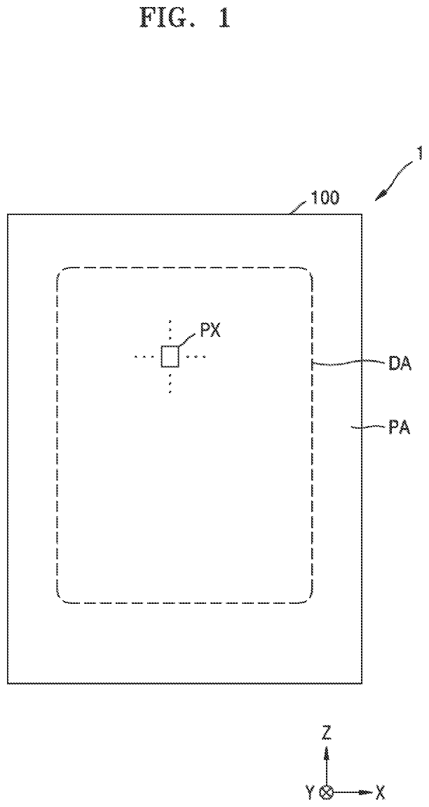

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. FIG. 1 is a schematic plan view of a display apparatus 1 according to some embodiments of the present disclosure.

Referring to FIG. 1, the display apparatus 1 according to some embodiments may be implemented as electronic apparatuses such as smartphones, mobile phones, navigation apparatuses, game consoles, televisions (TVs), head units for automobiles, notebook computers, laptop computers, tablet computers, personal multimedia players (PMPs), personal digital assistants (PDAs), and the like. In addition, an electronic apparatus may be a flexible apparatus.

A substrate 100 may be divided into a display area DA and a peripheral area PA around the display area DA.

The substrate 100 may include various materials such as glass, metal, or plastic. In some embodiments, the substrate 100 may include a flexible material. Here, the flexible material denotes a substrate that is easily warped, for example, is bendable, foldable, and/or rollable. The substrate 100 of the flexible material may include ultra-thin glass, metal, or plastic.

Sub-pixels PX including various display elements such as an organic light-emitting diode OLED may be arranged in the display area DA of the substrate 100. The sub-pixel PX may one of a plurality sub-pixels PX. The plurality of sub-pixels PX may be arranged in various configurations such as a stripe configuration, a pentile configuration, a mosaic configuration, and the like to display images.

In some embodiments, in a plan view, the display area DA may be a rectangular shape as shown in FIG. 1. In some embodiments, the display area DA may be provided in a polygonal shape such as a triangle, a pentagon, a hexagon, and the like, a circular shape, an elliptical shape, an irregular shape, or the like.

The peripheral area PA of the substrate 100 is a region arranged around the display area DA and may be a region in which images are not displayed. Pads may be arranged in the peripheral area PA, wherein various wirings, a printed circuit board or a driver integrated circuit (IC) chip configured to transfer electric signals to the display area DA are attached to the pads.

Hereinafter, for convenience of description, the display apparatus 1 including an organic light-emitting diode as the display element is described. However, embodiments of the present disclosure are applicable to various types of display apparatuses 1 such as liquid crystal display apparatuses, electrophoretic display apparatuses, and inorganic light-emitting display apparatuses.

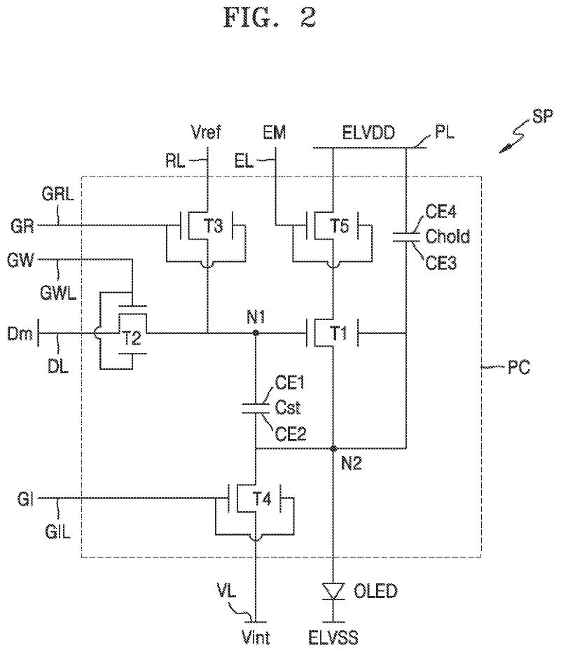

FIG. 2 is a schematic equivalent circuit diagram of a display element of the display apparatus 1 and a sub-pixel circuit electrically connected thereto according to some embodiments. As shown in FIG. 2, a sub-pixel PX may include a sub-pixel circuit PC and an organic light-emitting diode OLED electrically connected to the sub-pixel circuit PC.

As shown in FIG. 2, the sub-pixel circuit PC may include a plurality of thin-film transistors T1, T2, T3, T4, and T5, a first capacitor Cst, and a second capacitor Chold. The plurality of thin-film transistors T1, T2, T3, T4, and T5, the first capacitor Cst, and the second capacitor Chold may be connected to signal lines GWL, GRL, GIL, EL, and DL, an initialization voltage line VL, a reference voltage line RL, and a driving voltage line PL.

The plurality of thin-film transistors T1, T2, T3, T4, and T5 may include a driving transistor T1, a switching transistor T2, a reference voltage transistor T3, an initialization transistor T4, and an emission control transistor T5.

The plurality of thin-film transistors T1, T2, T3, T4, and T5 may be n-channel metal oxide semiconductor field-effect transistors (MOSFETs). The plurality of thin-film transistors T1, T2, T3, T4, and T5 may include an oxide semiconductor material.

The signal lines may include a first scan line GWL, a second scan line GRL, a third scan line GIL, an emission control signal line GWL, and a data line DL, wherein the first scan line GWL is configured to transfer a first scan signal GW, the second scan line GRL is configured to transfer a second scan signal GR, the third scan line GIL is configured to transfer a third scan signal GI, the emission control signal line EL is configured to transfer an emission controls signal, and the data line DL crosses the first scan line GWL and is configured to transfer a data signal Dm.

The initialization voltage line VL may be configured to transfer an initialization voltage Vint that initializes a sub-pixel electrode of the organic light-emitting diode OLED, the reference voltage line RL may be configured to transfer a reference voltage Vref to a gate electrode of the driving transistor T1, and the driving voltage line PL is configured to transfer a driving power voltage ELVDD which is a driving voltage.

A driving gate electrode of the driving transistor T1 may be connected to the first capacitor Cst through a first node N1, a drain region of the driving transistor T1 may be connected to the driving voltage line PL through the emission control transistor T5, and a source region of the driving transistor T1 may be electrically connected to the sub-pixel electrode of the organic light-emitting diode OLED through a second node N2. The driving transistor T1 may be configured to receive a data signal Dm and supply (e.g., selectively supply) a driving current to the organic light-emitting diode OLED according to a switching operation of the switching transistor T2. That is, the driving transistor T1 may be configured to control the amount of current flowing through the organic light-emitting diode OLED in response to a voltage applied to the first node N1 that changes according to a data signal Dm.

A switching gate electrode of the switching transistor T2 may be connected to the first scan line GWL that is configured to transfer a first scan signal GW, one of a source region and a drain region of the switching transistor T2 may be connected to the data line DL, and the other of the source region and the drain region of the switching transistor T2 may be connected to the driving gate electrode of the driving transistor T1 through the first node N1. The switching transistor T2 may be configured to transfer a data signal Dm from the data line DL to the first node N1 in response to a voltage applied to the first scan line GWL. That is, the switching transistor T2 may perform a switching operation of being turned on according to (e.g., in response to) a first scan signal GW (that is transferred through the first scan line GWL) and may transfer a data signal Dm to the driving transistor T1 through the first node N1 (the data signal Dm being transferred through the data line DL).

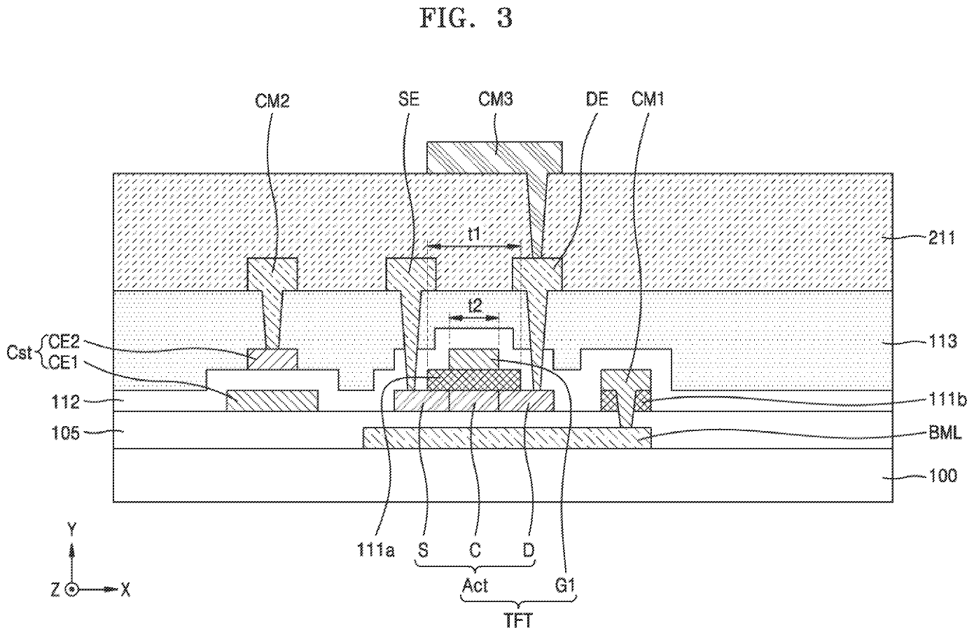

A reference voltage gate electrode of the reference voltage transistor T3 may be connected to the second scan line GRL that is configured to transfer a second scan signal GR, one of a source electrode and a drain electrode of the reference voltage transistor T3 may be connected to the reference voltage line RL, and the other of the source electrode and the drain electrode of the reference voltage transistor T3 may be connected to the driving gate electrode of the driving transistor T1 through the first node N1. The reference voltage transistor T3 may be configured to transfer the reference voltage Vref that is supplied from the reference voltage line RL to the first node N1 in response to a voltage applied to the second scan line GRL. The second scan line GRL may be the first scan line GWL that is adjacent to a sub-pixel PX shown in FIG. 3 and may belong to a sub-pixel of a previous row that is electrically connected to the same data line DL. Here, a second scan signal GR may be a previous writing signal (e.g., a previous scan signal).

An initialization gate electrode of the initialization transistor T4 may be connected to the third scan line GIL, one of a source region and a drain region of the initialization transistor T4 may be connected to the sub-pixel electrode of the organic light-emitting diode OLED through the second node N2, and the other of the source region and the drain region of the initialization transistor T4 may be connected to the initialization voltage line VL to receive the initialization voltage Vint. The initialization transistor T4 is turned on according to (e.g., in response to) a third scan signal GI that is transferred through the third scan line GIL and initializes the sub-pixel electrode of the organic light-emitting diode OLED. The third scan line GIL may be the first scan line GWL adjacent to the sub-pixel PX shown in FIG. 2 and may belong to a sub-pixel of the next row that is electrically connected to the same data line DL. Here, a third scan signal GI may be a next writing signal (e.g., a next scan signal).

An emission control gate electrode of the emission control transistor T5 may be connected to the emission control line EL, one of a source region and a drain region of the emission control transistor T5 may be connected to the driving voltage line PL, and the other of the source region and the drain region of the emission control transistor T5 may be connected to the drain region of the driving transistor T1. When the emission control transistor T5 is turned on according to (e.g., in response to) an emission control signal EM that is transferred through the emission control line EL, the driving power voltage ELVDD is transferred to the organic light-emitting diode OLED, and the driving current flows through the organic light-emitting diode OLED.

The first capacitor Cst is a storage capacitor and may include a first capacitor electrode CE1 and a second capacitor electrode CE2. The first capacitor electrode CE1 of the first capacitor Cst is connected to the driving gate electrode of the driving transistor T1 through the first node N21, and the second capacitor electrode CE2 of the first capacitor Cst is connected to the source region of the driving transistor T1 through the second node N2. The first capacitor Cst may be configured to store charge corresponding to a difference between a voltage of the driving gate electrode of the driving transistor T1 and the initialization voltage Vint.

The second capacitor Chold is a holding capacitor and may include a third capacitor electrode CE3 and a fourth capacitor electrode CE4. The third capacitor electrode CE3 of the second capacitor Chold may be connected to the source region of the driving transistor T1 through the second node N2, and the fourth capacitor electrode CE4 of the second capacitor Chold may be connected to the driving voltage line PL. A compensation voltage may be stored in the second capacitor Chold, wherein the compensation voltage is for compensating for a threshold voltage Vth of the driving transistor T1.

The operation of each sub-pixel PX according to some embodiments is further described below.

During an initialization period, when a third scan signal GI is supplied through the third scan line GIL, the initialization transistor T4 is turned on, and the sub-pixel electrode of the organic light-emitting diode OLED is initialized by the initialization voltage Vint supplied from the initialization voltage line VL. The source region of the driving transistor T1, which is electrically connected to the sub-pixel electrode of the organic light-emitting diode OLED, and the third capacitor electrode CE3 of the second capacitor Chold are initialized by the second node N2. As described above, the third scan line GIL may be the first scan line GWL that is adjacent to the sub-pixel PX shown in FIG. 3 and may belongs to a sub-pixel of the next row that is electrically connected to the same data line DL. Here, a third scan signal GI may be a next writing signal (e.g., a next scan signal).

During a compensation period, when a second scan signal GR is supplied through the second scan line GRL, the reference voltage transistor T3 is turned on, the reference voltage Vref supplied from the reference voltage line RL is transferred to the gate electrode G1 of the driving transistor T1 to compensate for the threshold voltage Vth of the driving transistor T1. A compensation voltage is stored in the second capacitor Chold, wherein the compensation voltage is for compensating for the threshold voltage Vth of the driving transistor T1. As described above, the second scan line GRL may be the first scan line GWL that is adjacent to the sub-pixel PX shown in FIG. 3 and may belong to a sub-pixel of the previous row that is electrically connected to the same data line DL. Here, a second scan signal GR may be a previous writing signal (e.g., a previous scan signal).

During a data programming period, when a first scan signal GW is supplied through the first scan line GWL, the switching transistor T2 is turned on in response to the first scan signal GW. Then, a voltage corresponding to a data signal Dm supplied from the data line DL is applied to the driving gate electrode G1 of the driving transistor T1. Because the first capacitor electrode CE1 of the first capacitor Cst is connected to the driving gate electrode G1 of the driving transistor T1 through the first node N1, and because the second capacitor electrode CE2 of the first capacitor Cst is connected to the third capacitor electrode CE3 of the second capacitor Chold (which is configured to store the compensation voltage in which the threshold voltage Vth of the driving transistor T1 is compensated for) through the second node N2, a data voltage in which the threshold voltage Vth of the driving transistor T1 is compensated for is stored in the first capacitor Cst.

During an emission period, the emission control transistor T5 is turned on according to (e.g., in response to) an emission control signal EM that is supplied from the emission control line EL. Because the first capacitor electrode CE1 of the first capacitor Cst is connected to the driving gate electrode G1 of the driving transistor T1 through the first node N1, and because the second capacitor electrode CE2 of the first capacitor Cst is connected to the source region of the driving transistor T1 through the second node N2, the driving current corresponding to a data signal Dm flows through the organic light-emitting diode OLED according to a data voltage stored in the first capacitor Cst , regardless of the threshold voltage Vth of the driving transistor T1.

As described above, the plurality of thin-film transistors T1, T2, T3, T4, and T5 may include an oxide semiconductor material. Because an oxide semiconductor has high carrier mobility and a low leakage current, a voltage drop is not large even when a driving time is long. That is, in the oxide semiconductor, because a color change of an image according to a voltage drop is not large even while the display apparatus is driven at low frequencies, the display apparatus may be driven at low frequencies. Accordingly, by allowing the plurality of thin-film transistors T1, T2, T3, T4, and T5 to include an oxide semiconductor material, a display apparatus with a reduced power consumption may be implemented in which the occurrence of a leakage current is prevented or substantially reduced.

Though it is shown in FIG. 2 that the sub-pixel circuit PC includes five transistors and two storage capacitors, embodiments of the present disclosure are not limited thereto. As an example, the sub-pixel circuit PC may include seven transistors and one capacitor.

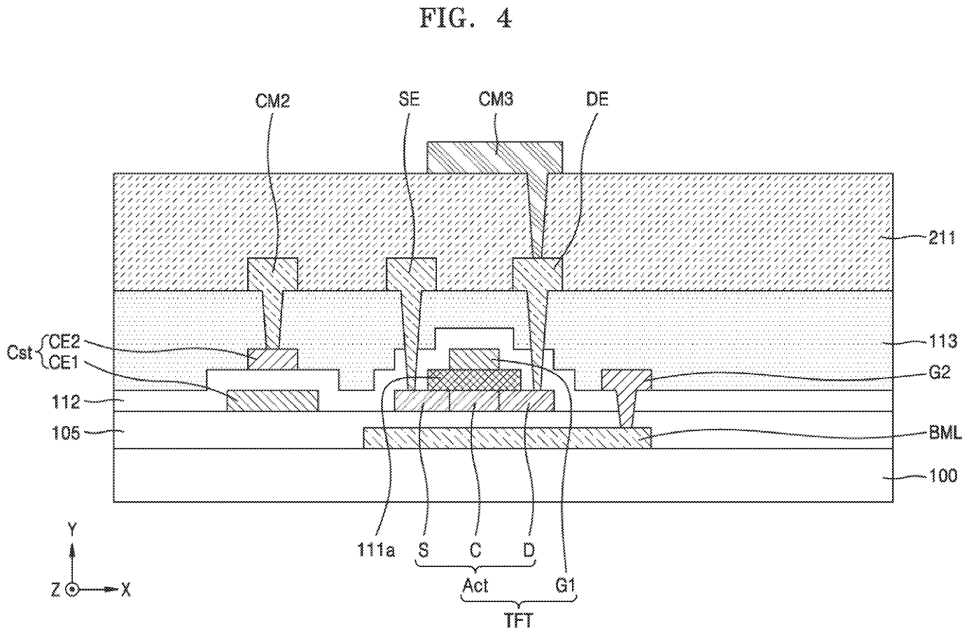

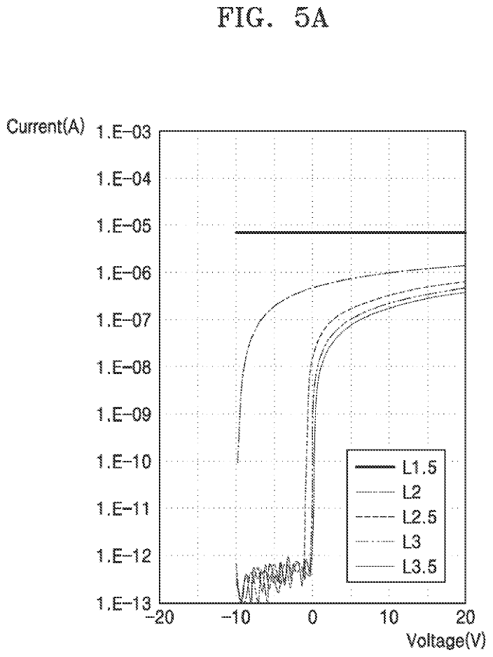

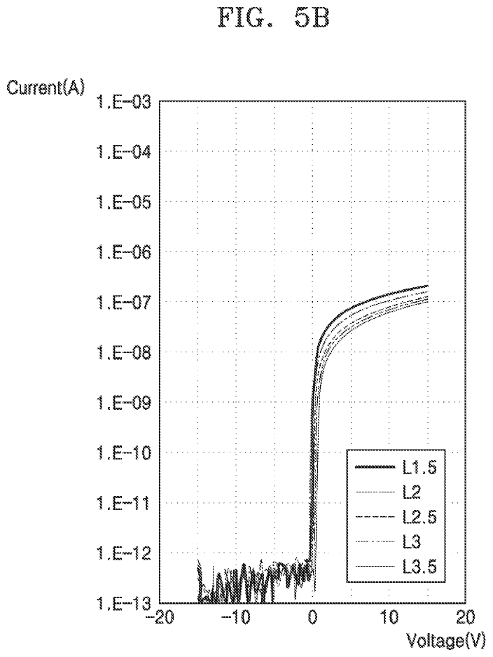

FIGS. 3 and 4 are schematic cross-sectional views of the display apparatus 1 according to some embodiments. FIGS. 5A and 5B are I(current)-V(voltage) graphs for a first semiconductor layer according to a length of a first gate electrode in the first direction.

Referring to FIG. 3, a bottom metal layer BML may be formed on the substrate 100, and a buffer layer 105 may be formed on the bottom metal layer BML. The substrate 100 may include a first base layer, a first barrier layer, a second base layer, and a second barrier layer. In some embodiments, the first base layer, the first barrier layer, the second base layer, and the second barrier layer may be sequentially stacked in the thickness direction of the substrate 100.

At least one of the first base layer and the second base layer may include a polymer resin including polyethersulfone, polyacrylate, polyetherimide, polyethylene naphthalate, polyethylene terephthalate, polyphenylene sulfide, polyimide, polycarbonate, cellulose tri acetate, cellulose acetate propionate, and/or the like.

The first barrier layer and the second barrier layer are barrier layers configured to prevent penetration of external foreign materials and may be a single layered structure or a multi-layered structure including inorganic materials such as silicon nitride (SiNₓ), silicon oxide (SiO₂), silicon oxynitride (SiON), and/or the like.

The bottom metal layer BML may be disposed on the substrate 100. The bottom metal layer BML may be arranged to overlap a first thin-film transistor TFT. The bottom metal layer BML may include aluminum (Al), platinum (Pt), palladium (Pd), silver (Ag), magnesium (Mg), gold (Au), nickel (Ni), neodymium (Nd), iridium (Ir), chromium (Cr), lithium(Li), calcium (Ca), molybdenum (Mo), titanium (Ti), tungsten (W), copper (Cu), and/or the like. The bottom metal layer BML may be a single layered structure or a multi-layered structure including the above material.

The buffer layer 105 may be disposed on the bottom metal layer BML. The buffer layer 105 may include an inorganic insulating material such as silicon nitride (SiNₓ), silicon oxynitride (SiON), silicon oxide (SiO₂), and/or the like, and include a single layered structure or a multi-layered structure including the inorganic insulating materials.

First, a first semiconductor layer Act may be disposed on the buffer layer 105. The first semiconductor layer Act may include an oxide semiconductor. The first semiconductor layer Act may include a channel region, a drain region, and a source region, where the drain region and the source region are on two opposite sides of the channel region.

A first gate electrode G1 may be disposed over the first semiconductor layer Act. The first semiconductor layer Act and the first gate electrode G1 may constitute the first thin-film transistor TFT. The first gate electrode G1 may overlap the channel region of the first semiconductor layer Act. The first gate electrode G1 may include a low-resistance metal material. The first gate electrode G1 may include a conductive material including molybdenum (Mo), aluminum (Al), copper (Cu), titanium (Ti), and/or the like, and have a single-layered structure or a multi-layered structure including the above material.

A first interlayer insulating layer 111a may be disposed between the first semiconductor layer Act and the first gate electrode G1. The first interlayer insulating layer 111a may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The first interlayer insulating layer 111a disposed between the first semiconductor layer Act and the first gate electrode G1 may have a first length t1 in a first direction (e.g., an x direction or a −x direction). The first gate electrode G1 disposed on the first interlayer insulating layer 111a may have a second length t2 in the first direction (e.g., the x direction or the −x direction). The first length t1 may be greater than the second length t2. However, embodiments of the present disclosure are not limited thereto.

In some embodiments, the length t1 in the first direction (e.g., the x direction or the −x direction) of the first interlayer insulating layer 111a disposed between the first semiconductor layer Act and the first gate electrode G1 may be the same or substantially the same as the second length t2 in the first direction (e.g., the x direction or the −x direction) of the first gate electrode G1 disposed on the first interlayer insulating layer 111a. In other words, the first length t1 of the first interlayer insulating layer 111a may be the same or substantially the same as the second length t2 of the first gate electrode G1. Depending on the characteristics of the thin-film transistor included in the sub-pixel circuit PC, the first length t1 may be same as the second length t2, or greater than the second length t2.

Characteristics of embodiments are described with reference to FIGS. 5A and 5B. FIG. 5A shows an I(current)-V(voltage) graph according to a length of the first gate electrode G1 when the length in the first direction (e.g., the x direction or the −x direction) of the first interlayer insulating layer 111a is the same or substantially the same as the length in the first direction of the first gate electrode G1. FIG. 5B shows an I(current)-V(voltage) graph according to a length of the first gate electrode G1 when the length in the first direction of the first interlayer insulating layer 111a is greater than the length in the first direction of the first gate electrode G1. The length of the first gate electrode G1 may be the same or substantially the same as the length of a channel region C of the first semiconductor layer Act.

In the case where the first semiconductor layer Act of the first thin-film transistor TFT includes an oxide semiconductor, the semiconductor layer may be doped (e.g., as n+) due to hydrogen (H₂) generated when a material for forming the first gate insulating layer 112 is deposited on the oxide semiconductor.

In the case where the first length t1 in the first direction (e.g., the x direction or the −x direction) of the first interlayer insulating layer 111a is the same or substantially the same as the second length t2 in the first direction of the first gate electrode G1, the upper surface of the first semiconductor layer Act may be exposed more to the first gate insulating layer 112 than the case where the first length t1 in the first direction of the first interlayer insulating layer 111a is greater than the second length t2 in the first direction of the first gate electrode G1. A portion of the upper surface of the first semiconductor layer Act exposed to the first gate insulating layer 112 may be doped (e.g., as n+) due to hydrogen (H₂) generated from the first gate insulating layer 112 during a subsequent process. In the case where the first length t1 in the first direction of the first interlayer insulating layer 111a is the same or substantially the same as the second length t2 in the first direction of the first gate electrode G1, at least a portion of the first semiconductor layer Act overlapping the first gate electrode G1 may be also doped (e.g., as n+). In other words, in the case where the first length t1 in the first direction of the first interlayer insulating layer 111a is the same or substantially the same as the second length t2 in the first direction of the first gate electrode G1, at least a portion of the channel region C of the first semiconductor layer Act may be doped (e.g., as n+). For example, about 1.86 μm of the first semiconductor layer Act overlapping the first gate electrode G1 may be doped (e.g., as n+). In other words, about 1.86 μm of the channel region C of the first semiconductor layer Act may be doped (e.g., as n+). The length in the first direction of the channel region C of the first semiconductor layer Act may be formed less by about 1.86 μm than the length in the first direction of the first gate electrode G1.

Referring to FIG. 5A, in the case where the length in the first direction (of the first gate electrode G1 is about 1.5 μm or about 2 μm, at least a portion of the first semiconductor layer Act disposed under the first gate electrode G1 to overlap the first gate electrode G1 may be entirely doped (e.g., as n+), and thus, the first thin-film transistor TFT may not serve as a switching transistor. In other words, the channel region C of the first semiconductor layer Act may be entirely doped (e.g., as n+), and thus, the first thin-film transistor TFT may not serve as a switching transistor. In the case where the length in the first direction of the first gate electrode G1 is about 1.5 μm or about 2 μm, a characteristic of a conductor in which current flows regardless of change in a voltage may be exhibited.

However, in the case where the length in the first direction of the first gate electrode G1 is about 2.5 μm, about 3 μm, or about 3.5 μm, even though at least a portion of the first semiconductor layer Act disposed under the first gate electrode G1 to overlap the first gate electrode G1 is entirely doped (e.g., as n+), a region of the first semiconductor layer Act not doped may remain, and thus, the first thin-film transistor TFT may serve as a switching transistor. In other words, because the channel region C of the first semiconductor layer Act remains, the first thin-film transistor TFT may serve as a switching transistor. In the case where the length in the first direction of the first gate electrode G1 is about 2.5 μm, about 3 μm, or about 3.5 μm, a characteristic of a switching transistor may appear in which a current does not flow under a preset voltage or less, but a current flows after a preset voltage is applied.

Because it is desirable for the mobility of electrons or holes to be high in the switching transistor, a short channel region C may be desired. However, for the first semiconductor Act to achieve the channel region C while the length t2 in the first direction of the first gate electrode G1 is the same or substantially the same as the first length t1 in the first direction of the first interlayer insulating layer 111a, the length in the first direction of the first gate electrode G1 may be 2.5 μm or more. Accordingly, the first semiconductor layer Act may not achieve a short channel region C. In other words, in the case where the length t2 in the first direction of the first gate electrode G1 is the same or substantially the same as the length t1 in the first direction of the first interlayer insulating layer 111a, the first semiconductor layer Act of the first thin-film transistor TFT may not achieve a short channel region C.

In the case where the first length t1 in the first direction (e.g., the x direction or the −x direction) of the first interlayer insulating layer 111a is greater than the second length t2 in the first direction of the first gate electrode G1, the area of the upper surface of the first semiconductor layer Act covered by the first interlayer insulating layer 111a may be greater than the case where the first length t1 in the first direction of the first interlayer insulating layer 111a is the same or substantially the same as the second length t2 in the first direction of the first gate electrode G1. In other words, in the case where the first length t1 in the first direction of the first interlayer insulating layer 111a is greater than the second length t2 in the first direction of the first gate electrode G1, the area of the upper surface of the first semiconductor layer Act exposed to the first gate insulating layer 112 may be less than the case where the first length t1 in the first direction of the first interlayer insulating layer 111a is the same or substantially the same as the second length t2 in the first direction of the first gate electrode G1.

At least a portion of the upper surface of the first semiconductor layer Act not exposed to the first gate insulating layer 112 by being covered by the first interlayer insulating layer 111a may not be doped (e.g., as n+) due to hydrogen (H₂) generated from the first gate insulating layer 112 during a subsequent process. Due to the first interlayer insulating layer 111a, at least a portion of the first semiconductor layer Act disposed under the first gate electrode G1 to overlap the first gate electrode G1 may not be doped (e.g., as n+). In the case where the length t1 in the first direction (e.g., the x direction or the −x direction) of the first interlayer insulating layer 111a is greater than the length t2 in the first direction of the first gate electrode G1, even though at least a portion of the upper surface of the first semiconductor layer Act covered by the first interlayer insulating layer 111a is doped (e.g., as n+), the channel region C of the first semiconductor layer Act may be achieve by the length t2 in the first direction of the first gate electrode G1. In other words, because the length t1 in the first direction of the first interlayer insulating layer 111a disposed on the first semiconductor layer Act is greater than the length t2 in the first direction of the first gate electrode G1, the short channel region C of the first semiconductor layer Act may be achieved.

Referring to FIG. 5B, in the case where the length t1 in the first direction (e.g., the x direction or the −x direction) of the first interlayer insulating layer 111a is greater than the length t2 in the first direction of the first gate electrode G1, even though the length in the first direction of the first gate electrode G1 is about 1.5 μm or about 2 μm, at least a portion of the first semiconductor layer Act covered by the first interlayer insulating layer 111a is not doped, and thus, the first thin-film transistor TFT may serve as a switching transistor. In other words, in the case where the length t1 in the first direction of the first interlayer insulating layer 111a is greater than the length t2 in the first direction of the first gate electrode G1, the channel region C of the first semiconductor layer Act may be provided to be about 1.5 μm or about 2 μm long, and thus, the first thin-film transistor TFT may serve as a switching transistor. Even in the case where the length in the first direction (of the first gate electrode G1 is about 1.5 μm or about 2 μm, a characteristic of a switching transistor may be exhibited by which a current does not flow under a preset voltage or less, and a current flows when the preset voltage or more is applied. In other words, the length in the first direction of the channel region C of the first semiconductor layer Act is about 1.5 μm or about 2 μm, a characteristic of a switching transistor may be exhibited by which a current does not flow under a preset voltage or less, and a current flows when the preset voltage or more is applied.

As described above, because it is desirable for the mobility of electrons or holes to be high in a switching transistor, securing a short channel region C may be desired. In the case where the length t1 in the first direction of the first interlayer insulating layer 111a is greater than the length t2 in the first direction of the first gate electrode G1, a short channel region C of the first semiconductor layer Act may be achieved.

In some embodiments, a second interlayer insulating layer 111b may be directly disposed on at least a portion of the buffer layer 105. The second interlayer insulating layer 111b may include the same or substantially the same material as the first interlayer insulating layer 111a. The second interlayer insulating layer 111b may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). A contact hole may be defined in the second interlayer insulating layer 111b. A first connection electrode CM1 may be disposed on the second interlayer insulating layer 111b. The first connection electrode CM1 may be electrically connected to the bottom metal layer BML through a contact hole defined in the second interlayer insulating layer 111b and the buffer layer 105. The first connection electrode CM1 may include the same or substantially the same material as the first gate electrode G1 disposed on the first interlayer insulating layer 111a. The first connection electrode CM1 may include a conductive material including molybdenum (Mo), aluminum (Al), copper (Cu), titanium (Ti), and/or the like, and have a single-layered structure or a multi-layered structure including the above material.

The bottom metal layer BML may be electrically connected to an electrode disposed on a second gate insulating layer 113. In some embodiments, a second connection electrode CM2 disposed on the second gate insulating layer 113 may be electrically connected to an upper electrode CE2 of a capacitor Cst. In other words, the second connection electrode CM2 may be electrically connected to the upper electrode CE2 of the capacitor Cst through a contact hole defined in the second gate insulating layer 113. A source electrode SE and a drain electrode DE disposed on the second gate insulating layer 113 may be respectively and electrically connected to a source region S and a drain region D of the semiconductor layer Act. In another expression, the source electrode SE and the drain electrode DE may be respectively and electrically connected to the source region S and the drain region D of the semiconductor layer Act through contact holes defined in the second gate insulating layer 113 and the first gate insulating layer 112. In the case where even the bottom metal layer BML is electrically connected to the electrode disposed on the second gate insulating layer 113, the number of contact holes defined in the second gate insulating layer 113 is too large, which makes it difficult to achieve a high resolution display using the display apparatus. In other words, in the case where even the bottom metal layer BML is electrically connected to the electrode disposed on the second gate insulating layer 113, the density of contact holes defined in the second gate insulating layer 113 is high, which makes it difficult to achieve a high resolution display using the display apparatus.

In some embodiments, because the bottom metal layer BML is electrically connected to the first connection electrode CM1 disposed on the second interlayer insulating layer 111b through a contact hole defined in the second interlayer insulating layer 111b and the buffer layer 105, the number of contact holes defined in the second gate insulating layer 113 may be reduced, which makes it easier to achieve a high resolution display using the display apparatus.

In some embodiments, a lower electrode CE1 may be disposed on at least a portion of the buffer layer 105. The lower electrode CE1 may include the same or substantially the same material as the first gate electrode G1 disposed on the first interlayer insulating layer 111a. The lower electrode CE1 may include a conductive material including molybdenum (Mo), aluminum (Al), copper (Cu), titanium (Ti), and/or the like, and have a single-layered structure or a multi-layered structure including the above material.

The first gate insulating layer 112 may cover the lower electrode CE1, the first gate electrode G1, and the first connection electrode CM1. The first gate insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The first gate insulating layer 112 may continuously cover the substrate 100.

The upper electrode CE2 may be disposed on the lower electrode CE1. The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), and/or the like, and include a single layered structure or a multi-layered structure including the above material. The upper electrode CE2 may overlap the lower electrode CE1 with the first gate insulating layer 112 therebetween. The upper electrode CE2 and the lower electrode CE1 may constitute the capacitor Cst.

In some embodiments, the second gate insulating layer 113 may be disposed on the upper electrode CE2. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The second connection electrode CM2, the source electrode SE, and the drain electrode DE may be disposed on the second gate insulating layer 113. The second connection electrode CM2, the source electrode SE, and the drain electrode DE may be disposed at the same layer and may include the same or substantially the same material. The second connection electrode CM2, the source electrode SE, and the drain electrode DE may each include a conductive material including molybdenum (Mo), aluminum (Al), copper (Cu), titanium (Ti), and/or the like, and have a single-layered structure or a multi-layered structure including the above material. As an example, the drain electrode DE and the source electrode SE may each have a multi-layered structure of Ti/Al/Ti.

The second connection electrode CM2 disposed on the second gate insulating layer 113 may be electrically connected to the upper electrode CE2 of the capacitor Cst through a contact hole defined in the second gate insulating layer 113. The source electrode SE disposed on the second gate insulating layer may be electrically connected to the source region S of the semiconductor layer Act through a contact hole defined in the second gate insulating layer 113 and the first gate insulating layer 112. The drain electrode DE disposed on the second gate insulating layer 113 may be electrically connected to the drain region D of the semiconductor layer Act through a contact hole defined in the second gate insulating layer 113 and the first gate insulating layer 112.

A first organic insulating layer 211 may be disposed on the second connection electrode CM2, the source electrode SE, and the drain electrode DE. The first organic insulating layer 211 may cover the second connection electrode CM2, the source electrode SE, and the drain electrode DE. The first organic insulating layer 211 may be continuously formed on the substrate 100. The first organic insulating layer 211 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A third connection electrode CM3 may be disposed on the first organic insulating layer 211. The third connection electrode CM3 may be electrically connected to the drain electrode DE or the source electrode SE through a contact hole defined in the first organic insulating layer 211. The third connection electrode CM3 may include a material having a high conductivity. The third connection electrode CM3 may include a conductive material including molybdenum (Mo), aluminum (Al), copper (Cu), titanium (Ti), and/or the like, and have a single-layered structure or a multi-layered structure including the above material. As an example, the third connection electrode CM3 may have a multi-layered structure of Ti/Al/Ti.

Referring to FIG. 4, in another embodiment, a second gate electrode G2 may be disposed on at least a portion of the first gate insulating layer 112. The second interlayer insulating layer 111b and the first connection electrode CM1 disposed on the second interlayer insulating layer 111b according to some embodiments may not be disposed. The second gate electrode G2 may include the same or substantially the same material as the upper electrode CE2 of the capacitor Cst. The second gate electrode G2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), and/or the like, and include a single layered structure or a multi-layered structure including the above material.

The second gate electrode G2 disposed on the first gate insulating layer 112 may be electrically connected to the bottom metal layer BML through a contact hole defined in the first gate insulating layer 112 and the buffer layer 105. As described above, because the second gate electrode G2 disposed on the first gate insulating layer 112 is electrically connected to the bottom metal layer BML, the number of contact holes defined in the second gate insulating layer may be reduced, which makes it easier to achieve a high resolution display using the display apparatus.

In some embodiments, because the length t1 in the first direction (e.g., the x direction or the −x direction) of the first interlayer insulating layer 111a is greater than the length t2 in the first direction (e.g., the x direction or the −x direction) of the first gate electrode G1, a transistor in which a high mobility and a short channel are achieved may be implemented, and a display apparatus of a high resolution may be implemented. In addition, because the bottom metal layer BML is electrically connected to the first connection electrode CM1 disposed on the second interlayer insulating layer 111b through a contact hole defined in the second interlayer insulating layer 111b and the buffer layer 105, a display apparatus of a high resolution may be implemented.

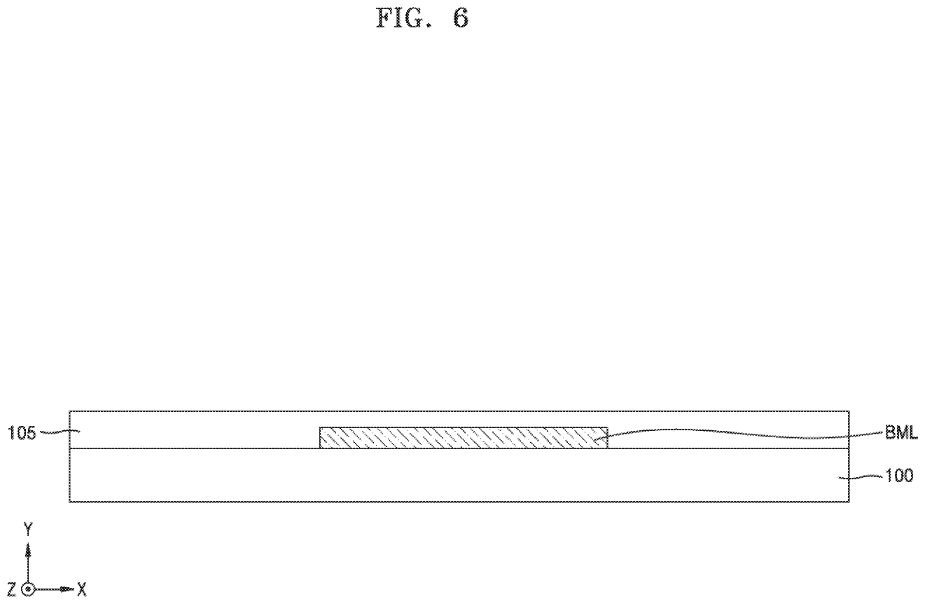

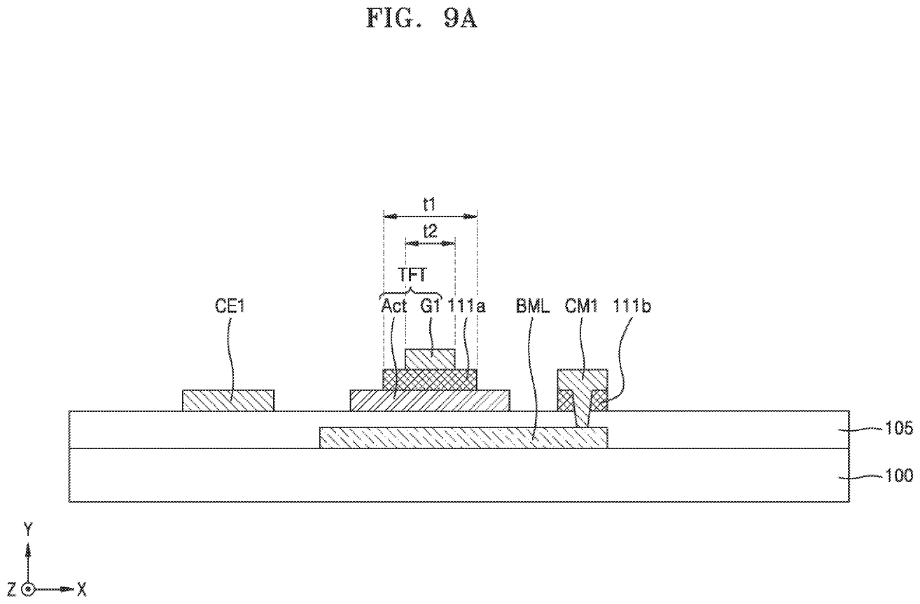

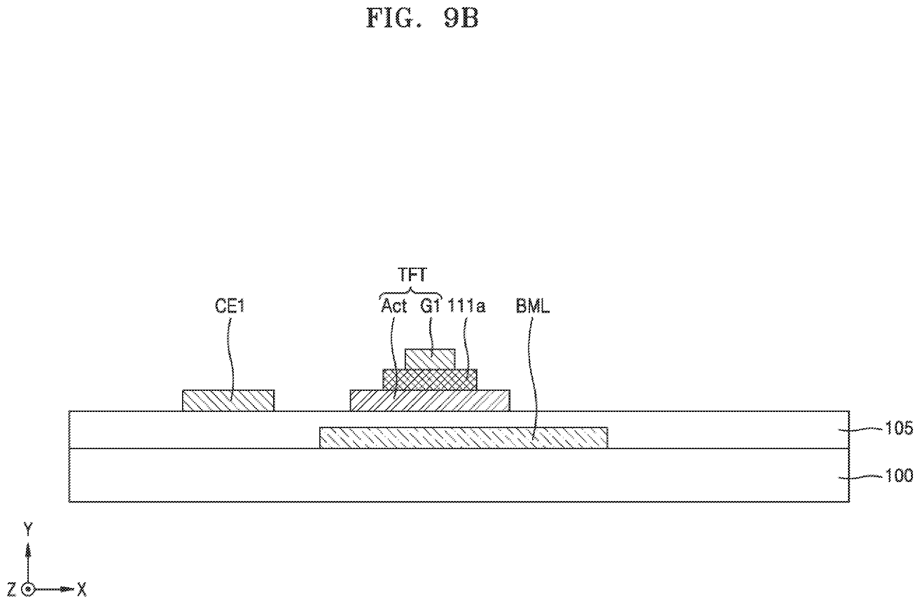

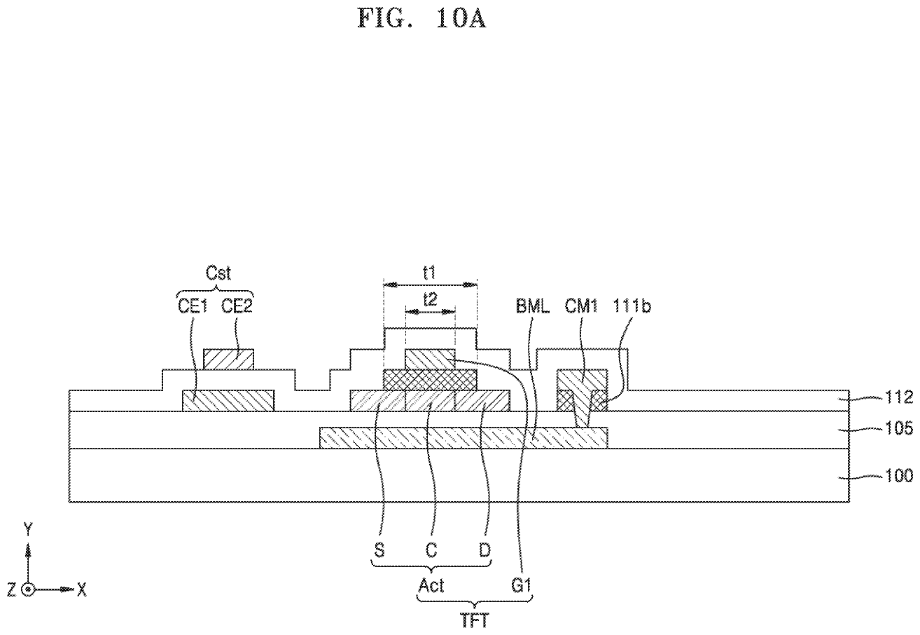

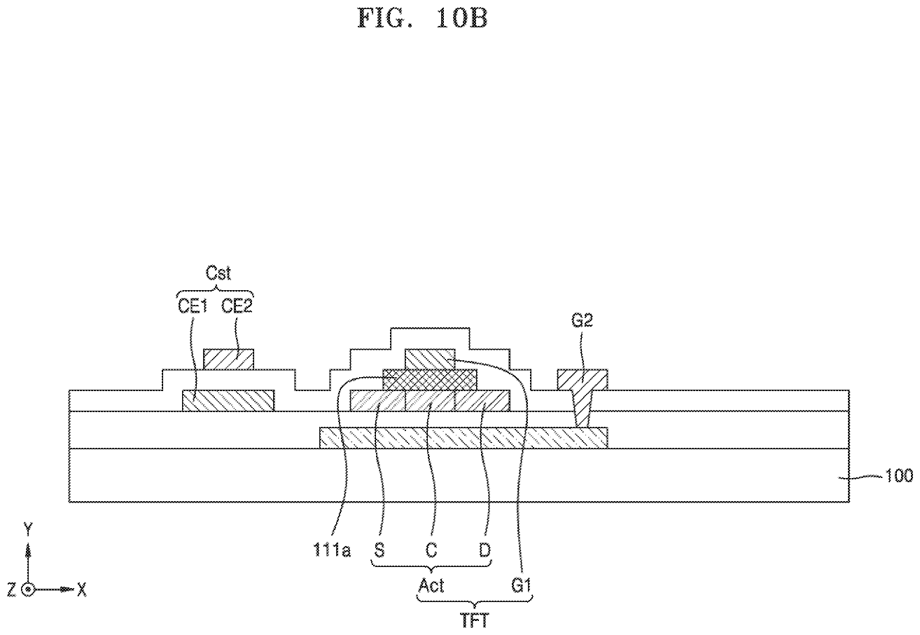

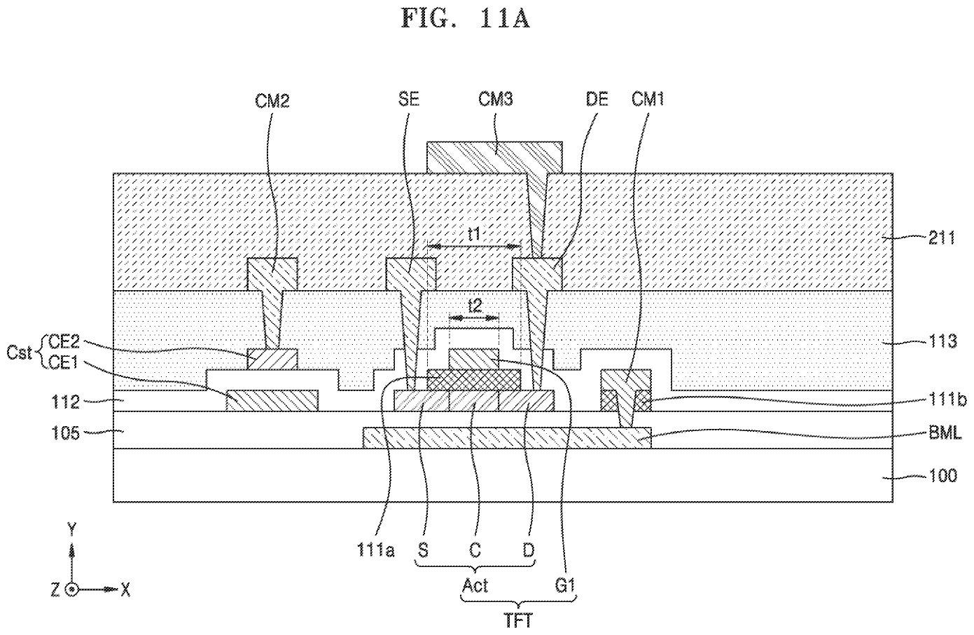

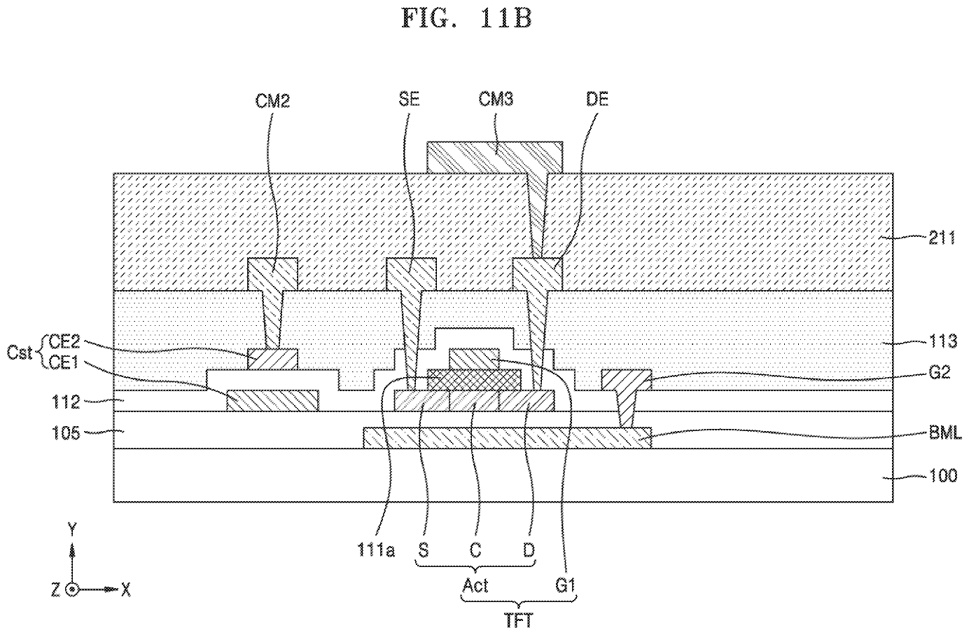

FIGS. 6, 7, 8A to 11A, and 8B to 11B are schematic cross-sectional views of the display apparatus 1, showing a method of manufacturing the display apparatus according to embodiments. FIGS. 6, 7, 8A to 11A, and 8B to 11B are schematic cross-sectional views showing a method of manufacturing the display apparatus 1 according to some embodiments, and FIGS. 6, 7, 8A to 11A, and 8B to 11B are schematic cross-sectional views showing a method of manufacturing the display apparatus 1 according to some other embodiments.

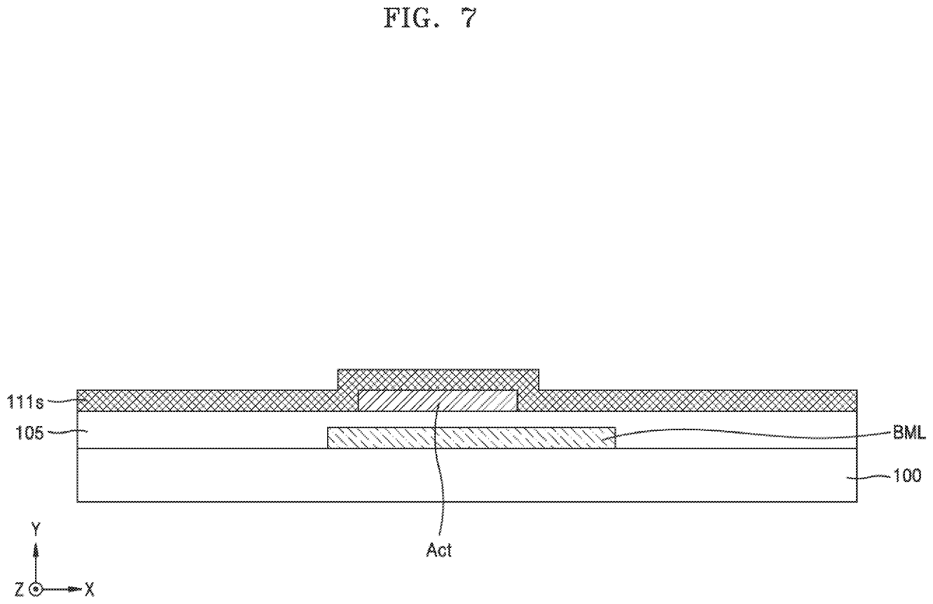

Referring to FIGS. 6 and 7, the bottom metal layer BML may be formed on the substrate 100. The bottom metal layer BML may include aluminum (Al), platinum (Pt), palladium (Pd), silver (Ag), magnesium (Mg), gold (Au), nickel (Ni), neodymium (Nd), iridium (Ir), chromium (Cr), lithium(Li), calcium (Ca), molybdenum (Mo), titanium (Ti), tungsten (W), copper (Cu), and/or the like. The bottom metal layer BML may be a single layered structure or a multi-layered structure including the above material.

The buffer layer 105 may be formed on the bottom metal layer BML. The first semiconductor layer Act including an oxide semiconductor may be formed on the buffer layer 105. The first semiconductor layer Act may overlap the bottom metal layer BML.

A material 111s for forming an interlayer insulating layer may be disposed on the first semiconductor layer Act. The material 111s for forming the interlayer insulating layer may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

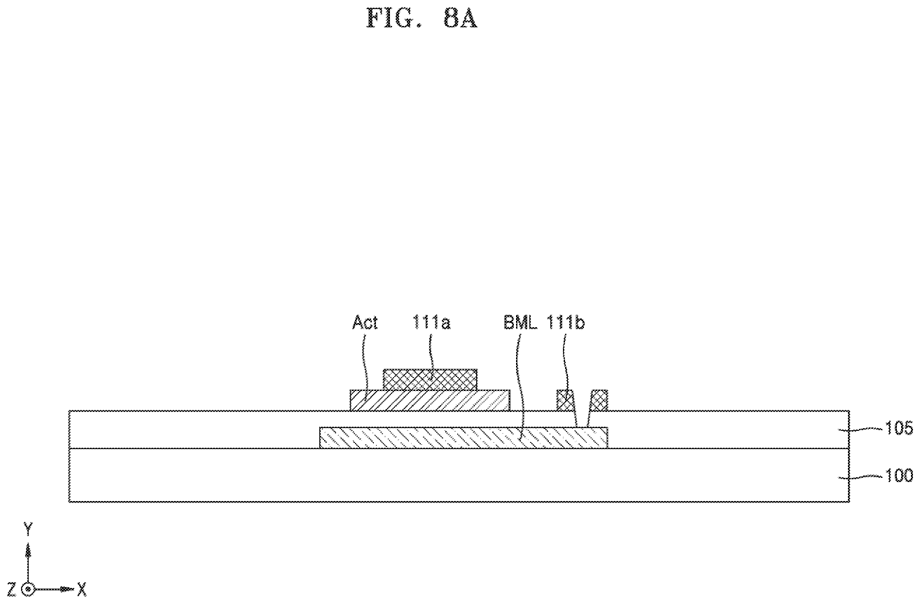

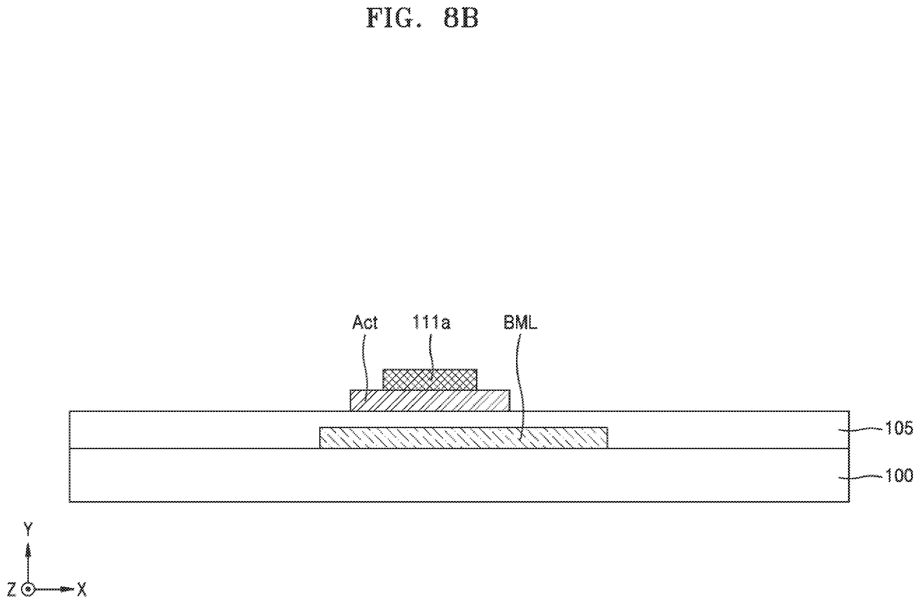

Referring to FIGS. 8A to 11A, the method of manufacturing the display apparatus 1 according to some embodiments may include forming the first interlayer insulating layer 111a and the second interlayer insulating layer 111b concurrently (e.g., simultaneously) by patterning the material 111s for forming the interlayer insulating layer. The forming of the first interlayer insulating layer 111a and the second interlayer insulating layer 111b by patterning the material 111s for forming the interlayer insulating layer is further described below. A photoresist may be disposed on the material 111s for forming the interlayer insulating layer. A portion of the photoresist other than a portion disposed on at least a portion of the first semiconductor layer Act as well as at least a portion of the buffer layer 105 may be removed. Then, through a dry etching process, a portion of the material 111s for forming the interlayer insulating layer on which the photoresist is not disposed may be removed to form the first interlayer insulating layer 111a and the second interlayer insulating layer 111b. The remaining photoresist disposed on the first interlayer insulating layer 111a and the second interlayer insulating layer 111b may be removed. During the forming of the first interlayer insulating layer 111a and the second interlayer insulating layer 111b by patterning the material 111s for forming the interlayer insulating layer, a contact hole may be defined in the second interlayer insulating layer 111b.

In some embodiments, the first gate electrode G1 may be formed on the first interlayer insulating layer 111a. The first gate electrode G1 may be formed on the first interlayer insulating layer 111a and, concurrently (e.g., simultaneously), the first connection electrode CM1 may be formed on the second interlayer insulating layer 111b. In addition, the first gate electrode G1 may be formed on the first interlayer insulating layer 111a and, concurrently (e.g., simultaneously), the lower electrode CE1 may be formed on at least a portion of the buffer layer 105. The first gate electrode G1 disposed on the first interlayer insulating layer 111a, the first connection electrode CM1 disposed on the second interlayer insulating layer 111b, and the lower electrode CE1 disposed on at least a portion of the buffer layer 105 may be formed during the same process and may include the same or substantially the same material. The first gate electrode G1, the first connection electrode CM1, and the lower electrode CE1 may include a low-resistance metal material. The first gate electrode G1, the first connection electrode CM1, and the lower electrode CE1 may each include a conductive material including molybdenum (Mo), aluminum (Al), copper (Cu), and titanium (Ti) and have a single-layered structure or a multi-layered structure including the above material.

The first thin-film transistor TFT may include the first semiconductor layer Act and the first gate electrode G1. The first interlayer insulating layer 111a may have the first length t1 in the first direction (e.g., the x direction or the −x direction). The first gate electrode G1 disposed on the first interlayer insulating layer 111a may have the second length t2 in the first direction . The first length t1 may be greater than the second length t2. As described above, it is desire for the switching transistor to have a short channel region. When the first interlayer insulating layer 111a is longer in the first direction than the first gate electrode G1, at least a portion of the first semiconductor layer Act covered by the first interlayer insulating layer 111a is not doped (e.g., as n+) due to hydrogen (H₂) emitted from the first gate insulating layer 112, and thus, the first semiconductor layer Act of the first thin-film transistor TFT may achieve a short channel region.

The first connection electrode CM1 disposed on the second interlayer insulating layer 111b may be electrically connected to the bottom metal layer BML through a contact hole defined in the second interlayer insulating layer 111b and the buffer layer 105. Because the bottom metal layer BML is electrically connected to the first connection electrode CM1 disposed on the second interlayer insulating layer 111b, the number of contact holes defined in the second gate insulating layer 113 described below may be reduced, which makes it easier to achieve a high resolution display using the display apparatus 1.

The first gate insulating layer 112 may be formed on the lower electrode CE1, the first gate electrode G1, and the first connection electrode CM1. The first gate insulating layer 112 may continuously cover the substrate 100. The first gate insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The upper electrode CE2 may be formed on the first gate insulating layer 112. In other words, the first gate insulating layer 112 may be disposed between the upper electrode CE2 and the lower electrode CE1. The upper electrode CE2 and the lower electrode CE1 may constitute the capacitor Cst. The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layered structure or a multi-layered structure including the above material.

The second gate insulating layer 113 may be formed on the first gate insulating layer 112. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second connection electrode CM2, the source electrode SE, and the drain electrode DE may be formed on the second gate insulating layer 113. Through a contact hole defined in the second gate insulating layer 113, the second connection electrode CM2 may be electrically connected to the upper electrode CE2 of the capacitor Cst, the source electrode SE may be electrically connected to the source region S of the first semiconductor layer Act, and the drain electrode DE may be electrically connected to the drain region D of the first semiconductor layer Act.

The first organic insulating layer 211 may be formed on the second connection electrode CM2, the source electrode SE, and the drain electrode DE. The first organic insulating layer 211 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A third connection electrode CM3 may be formed on the first organic insulating layer 211. The third connection electrode CM3 may be electrically connected to the source electrode SE or the drain electrode DE through a contact hole defined in the first organic insulating layer 211. The third connection electrode CM3 may include a conductive material including molybdenum (Mo), aluminum (Al), copper (Cu), titanium (Ti), and/or the like, and have a single-layered structure or a multi-layered structure including the above material. As an example, the third connection electrode CM3 may have a multi-layered structure of Ti/Al/Ti.

Referring to FIGS. 8B to 11B, the method of manufacturing the display apparatus 1 according to some other embodiments may include forming the first interlayer insulating layer 111a by patterning the material 111s for forming the interlayer insulating layer. The forming of the first interlayer insulating layer 111a by patterning the material 111s for forming the interlayer insulating layer is further described below. A photoresist may be disposed on the material 111s for forming the interlayer insulating layer. A portion of the photoresist except for a portion of the photoresist disposed on at least a portion of the first semiconductor layer Act may be removed. Then, through a dry etching process, a portion of the material 111s for forming the interlayer insulating layer on which the photoresist is not disposed may be removed to form the first interlayer insulating layer 111a. A photoresist remaining on the first interlayer insulating layer 111a may be removed.

In some embodiments, the first gate electrode G1 may be formed on the first interlayer insulating layer 111a. Concurrently (e.g., simultaneously), a lower electrode CE1 may be formed on at least a portion of the buffer layer 105. The first gate electrode G1 disposed on the first interlayer insulating layer 111a, and the lower electrode CE1 disposed on the buffer layer 105 may be formed during the same process and may include the same or substantially the same material.

The first gate insulating layer 112 may be formed on the lower electrode CE1 and the first gate electrode G1, and the upper electrode CE2 may be formed on the first gate insulating layer 112. The upper electrode CE2 and the lower electrode CE1 may constitute the capacitor Cst.

The second gate electrode G2 may be formed on at least a portion of the first gate insulating layer 112. During an operation of forming the second gate electrode G2, the upper electrode CE2 of the capacitor Cst may be concurrently (e.g., simultaneously) formed. The second gate electrode G2 may include the same or substantially the same material as the upper electrode CE2 of the capacitor Cst. The second gate electrode G2 and the upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), and/or the like, and include a single layered structure or a multi-layered structure including the above material.

The second gate electrode G2 may be electrically connected to the bottom metal layer BML through a contact hole defined in the first gate insulating layer 112 and the buffer layer 105. As described above, because the second gate electrode G2 is electrically connected to the lower metal layer BML, the density of contact holes defined in the second gate insulating layer 113 is reduced, which makes it easier to achieve a high resolution display using the display apparatus 1.

The second gate insulating layer 113 may be formed on the upper electrode CE2 and the second gate electrode G2. The second connection electrode CM2, the source electrode SE, and the drain electrode DE may be formed on the second gate insulating layer 113. Through contact holes defined in the second gate insulating layer 113, the second connection electrode CM2 may be connected to the upper electrode CE2, the source electrode SE may be connected to the source region S of the first semiconductor layer Act, and the drain electrode DE may be electrically connected to the drain region D of the first semiconductor layer Act.

The first organic insulating layer 211 may be formed on the second connection electrode CM2, the source electrode SE, and the drain electrode DE. A third connection electrode CM3 may be formed on the first organic insulating layer 211. The third connection electrode CM3 may be electrically connected to the source electrode SE or the drain electrode DE through a contact hole defined in the first organic insulating layer 211.

In the related art, the length t1 in the first direction (e.g., the x direction or the −x direction) of the first interlayer insulating layer 111a disposed on the first semiconductor layer Act is the same or substantially the same as the length t2 in the first direction of the first gate electrode G1 disposed on the first interlayer insulating layer 111a. The length t2 in the first direction of the first gate electrode G1 may be the same or substantially the same as the length in the first direction of the channel region C of the first semiconductor layer Act. Because not only the first semiconductor layer Act exposed to the first gate insulating layer 112 (by not being covered by the first interlayer insulating layer 111a) but also at least a portion of the first semiconductor layer Act covered by the first interlayer insulating layer 111a is doped (e.g., as +n), a short channel region C of the first semiconductor layer Act cannot be achieved.

In addition, because the bottom metal layer BML is electrically connected to the electrode disposed on the second gate insulating layer 113 through a contact hole defined in the second gate insulating layer 113, the number of contact holes defined in the second gate insulating layer 113 increases, which makes it difficult to achieve a high resolution display using the display apparatus 1.

According to some embodiments, because the length t1 in the first direction of the first interlayer insulating layer 111a is formed greater than the length t2 in the first direction of the first gate electrode G1, the area of the upper surface of the first semiconductor layer Act exposed to the first gate insulating layer 112 may be reduced. Because the area of the upper surface of the first semiconductor layer Act covered by the first interlayer insulating layer 111a increases, even though at least a portion of the first semiconductor layer Act covered by the first interlayer insulating layer 111a is doped (e.g., as n+), the first semiconductor layer Act may achieve a short channel region C.

Because the bottom metal layer BML is electrically connected to the first connection electrode CM1 disposed on the second interlayer insulating layer 111b through a contact hole defined in the second interlayer insulating layer 111b, the number of contact holes defined in the second gate insulating layer 113 may be reduced, which makes it easier to achieve a high resolution display using the display apparatus 1.

According to some embodiments having the above configuration, the display apparatus with a high resolution, and the method of manufacturing the display apparatus may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

1 What is claimed is:

1. A display apparatus comprising:
a substrate having a display area in which display elements are arranged;
a first thin-film transistor in the display area and comprising a first semiconductor layer and a first gate electrode, the first semiconductor layer comprising an oxide semiconductor and the first gate electrode being insulated from the first semiconductor layer; and
a first interlayer insulating layer between the first semiconductor layer and the first gate electrode,
wherein the first interlayer insulating layer on the first semiconductor layer has a first length in a first direction,
wherein the first gate electrode on the first interlayer insulating layer has a second length in the first direction, and
wherein the first length is greater than the second length.

2. The display apparatus of claim 1, further comprising a first gate insulating layer covering the first gate electrode.

3. The display apparatus of claim 2, further comprising:
a bottom metal layer on the substrate; and
a buffer layer on the bottom metal layer.

4. The display apparatus of claim 3, further comprising a second interlayer insulating layer directly on at least a portion of the buffer layer and defining a contact hole therein.

5. The display apparatus of claim 4, further comprising a first connection electrode on the second interlayer insulating layer.

6. The display apparatus of claim 5, wherein the first connection electrode is electrically connected to the bottom metal layer through a contact hole defined in the second interlayer insulating layer and the buffer layer.

7. The display apparatus of claim 3, further comprising:
a lower electrode directly on the buffer layer; and
an upper electrode over the lower electrode,
wherein the upper electrode and the lower electrode form a capacitor.

8. The display apparatus of claim 7, wherein the first gate insulating layer is between the lower electrode and the upper electrode.

9. The display apparatus of claim 3, further comprising a second gate electrode on the first gate insulating layer.

10. The display apparatus of claim 9, wherein the second gate electrode is electrically connected to the bottom metal layer through a contact hole defined in the first gate insulating layer and the buffer layer.

11. The display apparatus of claim 7, further comprising:
a second gate insulating layer on the first gate insulating layer; and
a second connection electrode, a source electrode, and a drain electrode on the second gate insulating layer.

12. The display apparatus of claim 11, wherein the second connection electrode is electrically connected to the upper electrode of the capacitor through a contact hole defined in the first interlayer insulating layer, and
wherein the source electrode and the drain electrode are electrically connected to the first semiconductor layer through contact holes defined in the first interlayer insulating layer.

13. The display apparatus of claim 11, further comprising:
a first organic insulating layer on the second connection electrode; and
a third connection electrode on the first organic insulating layer.

14. The display apparatus of claim 13, wherein the third connection electrode is electrically connected to the source electrode or the drain electrode through a contact hole defined in the first organic insulating layer.

15. A method of manufacturing a display apparatus, the method comprising:
forming a first semiconductor layer on a substrate, the first semiconductor layer comprising an oxide semiconductor;
positioning a material for forming an interlayer insulating layer on the first semiconductor layer;
forming a first interlayer insulating layer by patterning the material for forming the interlayer insulating layer; and
forming a first gate electrode on the first interlayer insulating layer,
wherein the first interlayer insulating layer on the first semiconductor layer has a first length in a first direction,
wherein the first gate electrode on the first interlayer insulating layer has a second length in the first direction, and
wherein the first length is greater than the second length.

16. The method of claim 15, further comprising, before the forming of the first semiconductor layer on the substrate:
forming a bottom metal layer on the substrate; and
forming a buffer layer on the bottom metal layer, wherein the first semiconductor layer comprises the oxide semiconductor.

17. The method of claim 16, wherein, during the forming of the first interlayer insulating layer by patterning the material for forming the interlayer insulating layer, a second interlayer insulating layer is formed by patterning the material for forming the interlayer insulating layer.

18. The method of claim 17, wherein, during the forming of the first gate electrode on the first interlayer insulating layer, a first connection electrode is formed on the second interlayer insulating layer, and a lower electrode is formed on the buffer layer.

19. The method of claim 18, wherein the first connection electrode is electrically connected to the bottom metal layer through a contact hole defined in the second interlayer insulating layer.

20. The method of claim 18, further comprising:
forming a first gate insulating layer on the first gate electrode, the lower electrode, and the first connection electrode; and
forming an upper electrode on the first gate insulating layer,
wherein the upper electrode and the lower electrode constitute a capacitor.
